(19) United States
(12) Patent Application Publication
(10) Pub. No.: US 2003/0228768 A1
(43) Pub. Date: Dec. 11, 2003

(54) Dielectric etching with reduced striation

(75) Inventors: Heeyeop Chae, San Jose, CA (US); Gerardo Delgadino, Santa Clara, CA (US); Xiaoye Zhao, Mountain View, CA (US); Yan Ye, Santa Clara, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/163,607

(22) Filed: Jun. 5, 2002

(51) Int. Cl. H01L 21/302; H01L 21/461

(52) U.S. Cl. 438/710

(57) ABSTRACT

The present invention provides a dielectric etch process with good etch rate, good selectivity with respect to photoresist mask, and much reduced striation as compared with conventional dielectric etching processes having comparable etch rate and selectivity. In one embodiment of the present invention, the dielectric layer is formed on a substrate with an underlying layer of another material and an overlying photoresist mask. A process for etching the dielectric layer comprises introducing a novel process gas into a process zone and maintaining a plasma of the process gas for a period of time. The process gas comprises a fluorocarbon gas, oxygen, a hydrogen-containing gas, and, optionally, an inert gas.

The present application relates to semiconductor processing technologies, and particularly to plasma etching processes.

### BACKGROUND

Integrated circuit fabrication typically requires the etching of openings such as contacts and vias in layers of insulative dielectric materials. The dielectric materials include silicon oxide, silicate glasses such as phosphate silicate glass (PSG) and boron phosphate silicate glass (BPSG), doped or undoped thermally grown silicon oxide, doped or undoped TEOS deposited silicon oxide, etc. The dielectric materials also include some low-k dielectrics such as fluorine and carbon doped silicon oxide films formed by CVD processes using precursors such as SiH₂F₂ or CH₃SiH₃. These materials are often used in integrated circuits to electrically isolate devices, interconnect metal lines, or other features formed on a substrate.

The dielectric layer is typically etched using a plasma of a process gas comprising a fluorocarbon or hydro-fluorocarbon gas, and one or more other gases. For example, commonly assigned U.S. Pat. No. 5,814,563, which is incorporated herein by reference, discloses a process gas composition comprising: (i) a hydro-fluorocarbon gas for forming fluorine-containing etchant species capable of etching the dielectric layer, and for forming passivating polymeric deposits on the etched feature surfaces; (ii) NH₃ generating gas for enhancing etching rates of the fluorine-containing etchant species by adsorbing onto the feature surfaces, and (iii) carbon-oxygen gas for increasing selectivity with respect to an underlying polysilicon layer and enhancing the formation of polymeric deposits on the sidewalls of etched features to provide anisotropic etching.

The etching process disclosed in the U.S. Pat. No. 5,814,563 patent provides a rapid etch rate with excellent etching selectivities. But under certain conditions, the etched micro-optimum performance of the integrated circuits because the rough feature surface makes metallization difficult. Also, the etching process disclosed in the U.S. Pat. No. 5,814,563 patent was very costly to use in practical integrated circuit fabrication because the heavy polymer deposition associated with the process requires frequent chamber cleaning.

Therefore, there is a need for a dielectric etching process that provides satisfactory etching characteristics, such as etch rate and etching selectivities with respect to adjacent layers, with reduced striation. There is also a need for an efficient and economic chamber cleaning technique for removing polymeric deposits inside the etching chamber after a dielectric etch process is performed.

### SUMMARY

The present invention provides a dielectric etching process with good etch rate, good selectivity with respect to photoresist mask, and much reduced striation as compared with conventional dielectric etching processes having comparable etch rate and selectivity. In one embodiment of the present invention, the dielectric layer is formed on a substrate with an underlying layer of another material, such as polysilicon or silicon nitride, and an overlying photoresist mask. A process for etching the dielectric layer comprises introducing a novel process gas into a process zone, in which the substrate is placed, and maintaining a plasma of the process gas for a period of time. The process gas comprises a fluorocarbon gas, oxygen, a hydrogen-containing gas, and, optionally, an inert gas, wherein the volumetric flow ratio of fluorocarbon:hydrogen-containing gas is about 5:2 to 5:1. The etching process provides an etch rate greater than 4000 Å/min, and an etching selectivity with respect to photoresist mask greater than 4.5:1.

The present invention further includes a cleaning process for cleaning surfaces around the process zone after the substrate has been etched and removed from the process zone. The cleaning process comprises the steps of introducing a cleaning gas into the process zone, the cleaning gas being oxygen, nitrogen, or mixtures thereof; and maintaining a plasma of the cleaning gas by coupling power into the process zone such that the DC voltage between the plasma and the surfaces surrounding the process zone is not significant.

### DRAWINGS

Additional objects and features of the invention will be more readily apparent from the following detailed description and appended claims when taken in conjunction with the drawings, in which:

FIGS. 1(a)-(d) are schematics in vertical cross-section of a dielectric layer on a substrate at different stages of an etch process;

FIG. 2 is schematic view in vertical cross-section of an exemplary plasma reactor suitable for practicing a dielectric etching process according to one embodiment of the present invention;

FIG. 3 is schematic view in vertical cross-section of an exemplary plasma reactor suitable for practicing a dielectric etching process according to an alternative embodiment of the present invention;

FIG. 4 includes drawings of the peripherals of features etched using two different process gases;

FIG. 5 is a chart showing the trend of change in etch rate and etching selectivity in response to change in NH₃ flow rate according to one embodiment of the present invention.

FIG. 6 is a chart showing the trend of change in etch rate and etching selectivity in response to change in C₄F₆ (O₂) flow rate according to one embodiment of the present invention.

FIG. 7 includes a chart and drawings of the peripherals of etched features showing the trend of change in etch rate, etching selectivity, and degree of striation in etched features in response to change in Argon flow rate according to one embodiment of the present invention.

FIG. 8 includes a chart and drawings of the peripherals of etched features showing the trend of change in etch rate, etching selectivity, and degree of striation in etched features in response to change in power coupled into the process zone from a first power source according to one embodiment of the present invention.

FIG. 9 is a chart showing the trend of change in etch rate and etching selectivity in response to change in power coupled into the process zone from a second power source according to one embodiment of the present invention.

FIG. 10 is a chart showing the trend of change in etch rate and etching selectivity in response to change in a slowly rotating magnetic field in the process zone according to one embodiment of the present invention.

FIG. 11 includes graphs of Energy-Dispersive X-Ray Spectroscopy analysis of atomic composition of passivating films on etched feature surfaces.

FIG. 12 includes drawings of the peripherals of features etched using two different power levels in top-down and vertical cross-sectional view of the features.

### DESCRIPTION

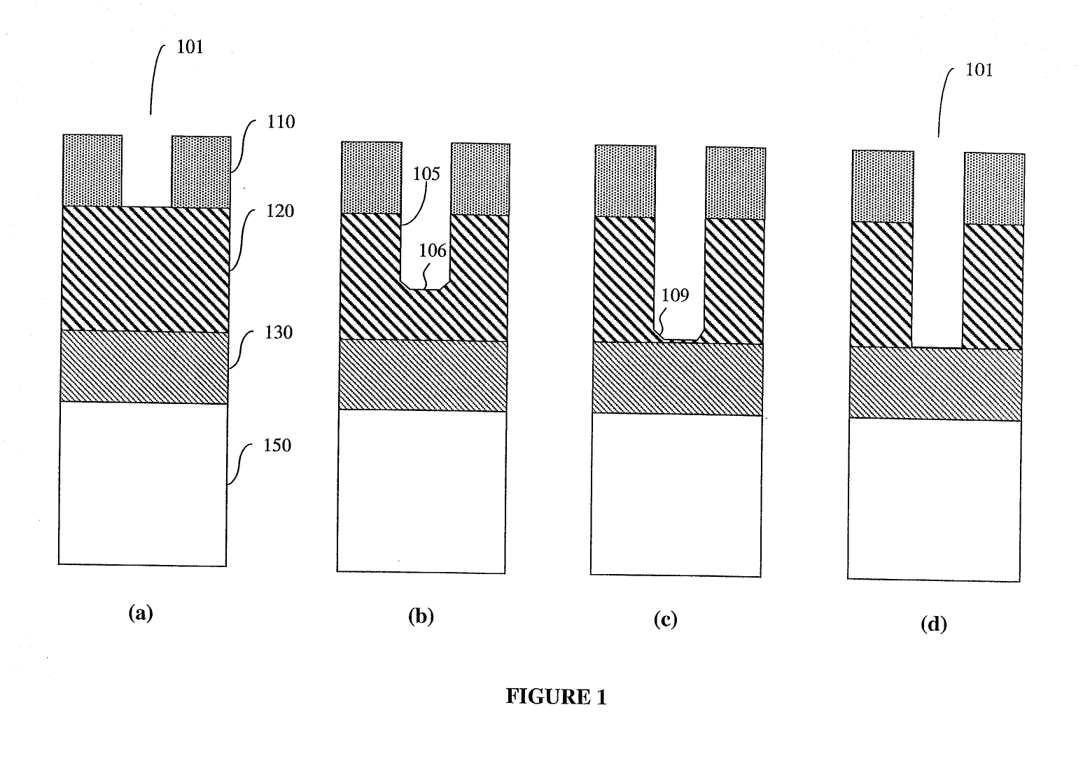

FIGS. 1(a), 1(b), 1(c) and 1(d) illustrate a dielectric layer 120 on a substrate 150 at different, successive stages of an etching process. A patterned mask layer 110 partially covers the dielectric layer 120 and defines the openings for features to be etched, such as feature 101. A layer 130 of another material, such as polysilicon, silicon nitride, metal, or barrier/liner material, etc., may lie under at least a portion of the dielectric layer 120, and is shown here to lie under the feature 101 to be etched. A thin antireflective coating (ARC) layer (not shown) may lie between the mask layer 110 and the dielectric layer 120. The ARC layer is typically used for line/width control during photolithography when the minimum feature sizes reach below quarter micron. An ARC open process can be used to etch away the ARC layer at the feature openings.

The etching process of the present invention is useful for etching the dielectric layer 120 with good etch rates, high etching selectivities with respect to the mask 110, and much reduced striation as compared to conventional processes. Etching selectivity means the ratio of the rate of etching the dielectric layer 120 to the rate of etching one of the adjacent layers of other materials, such as the overlying photoresist mask 110. The etching process of the present invention can also be used to etch films of other materials, and is not limited to etching dielectric layers.

In one embodiment of the present invention, the dielectric layer 120 comprises a layer of silicon oxide, phosphosilicate glass (PSG), or borophosphosilicate glass (BPSG), having a thickness of about 400 to 1500 nm. The mask layer is photoresist, such as “RISTON,” manufactured by duPont de Nemours Chemical Company. The thickness of the mask layer is typically about 250 to 700 nm. Various layers of the same or other materials may lie under the dielectric layer 120, which should not affect the practice of the present invention.

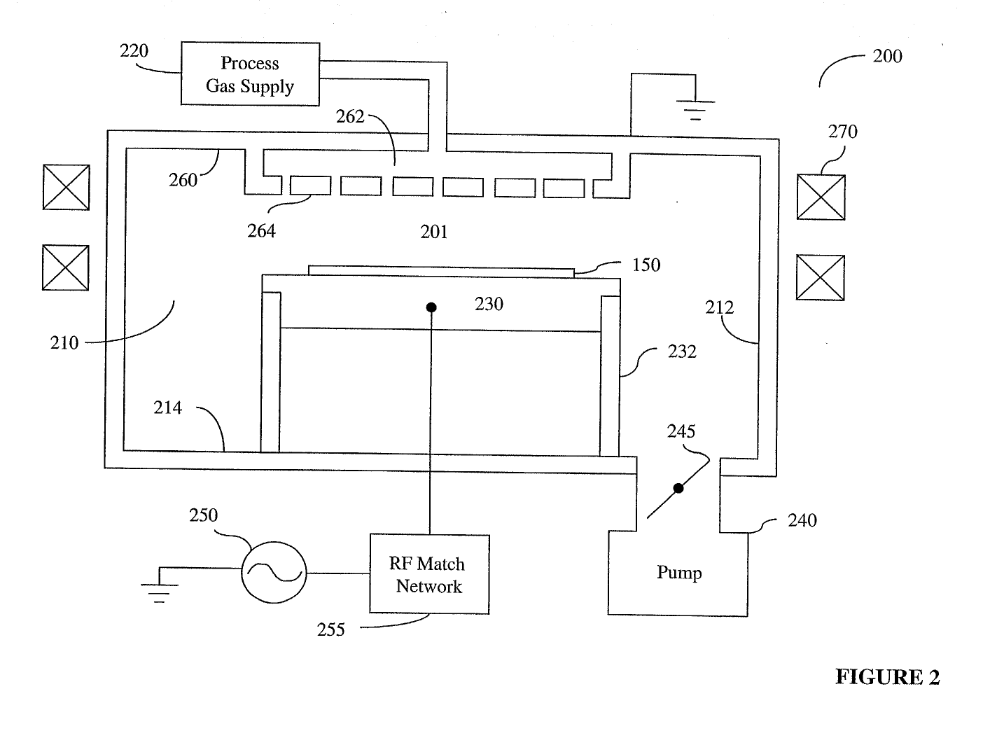

As described in more detail below, the etching process is performed by exposing the uncovered portion of the dielectric layer 120 to an energized gas, such as a plasma, comprising energetic and reactive species. The plasma is usually generated in a plasma reactor, such as, for example, a magnetically enhanced reactive ion etching (MERIE) reactor 200, commercially available from Applied Materials Inc., Santa Clara, Calif., as illustrated in FIG. 2. The reactor 200 comprises a chamber 210 enclosed by a wall 212, a base 214, and a ceiling 260. The chamber includes a process zone 201 comprising a volume of about 5,000 to about 50,000 cm³. The reactor 200 further comprises a process gas supply 220 that supplies process gases into the chamber 210 through a gas manifold 262 and a gas distribution plate (GDP) 264 at the ceiling 260 of the chamber 210. Spent process gas and etch products are pumped out by one or more pumps from an opening at the base 214. A throttle valve 245 at the opening controls the pressure in the chamber 210. The wall 212, the base 214, the ceiling 260 and the GDP 264 are usually made of aluminum with anodized aluminum coating on at least the surfaces facing the inside of the chamber 210, and are typically grounded. The chamber 210 further includes a pedestal 230 that supports the substrate 150 in the chamber 210. The pedestal 230 is electrically isolated from the base 214 by an insulator support ring 232, and is connected to a radio frequency (RF) power source 250 through an impedance match network 255.

To perform the etching process, the chamber 210 is evacuated by the pump 240 to a pressure of less than about 1 mTorr, and the throttle valve 245 at the base 214 controls the pressure in the chamber 210. The substrate 150 is transferred into the chamber 210 from a load lock transfer chamber (not shown) maintained at near vacuum, and is placed on the pedestal 230. The substrate 150 can be held in place during the etching process using a mechanical or electrostatic chuck (not shown) with grooves in which a coolant gas, such as helium, is circulated to control the temperature of the substrate 150.

Process gases are introduced into the chamber through the GDP 264 over the substrate 150. Once the pressure in the chamber 210 is stabilized at a desired level, the RF power source 250 is turned on to strike a plasma in the process zone 201 in the chamber 210. With the RF source 250 turned on, the pedestal 230 acts as a cathode electrode, while the grounded wall 212, ceiling 260 and the GDP 264 together serve as an anode electrode. The reactor configuration of FIG. 1 facilitates reactive ion etching (RIE) processes, wherein an RF voltage at a power level of from about 100 to about 2000 Watts is applied to the cathode electrode under the substrate 150 while the anode electrode(s) are grounded. The plasma is thus maintained by capacitively coupled RF power between the cathode and the anode electrodes. The plasma density, defined by the number of ions per unit volume, may be enhanced by placing plural magnets 270 around the chamber wall 212 to provide a slowly rotating magnetic field in the chamber 210. The magnets may be electromagnets driven with respective phases of a low frequency (e.g., 0.1-0.5 Hertz) AC current source (not shown). Alternatively, the magnets may be permanent magnets mounted on a slowly rotating support structure (not shown) rotating at, for example, 0.1-0.5 revolutions per second.

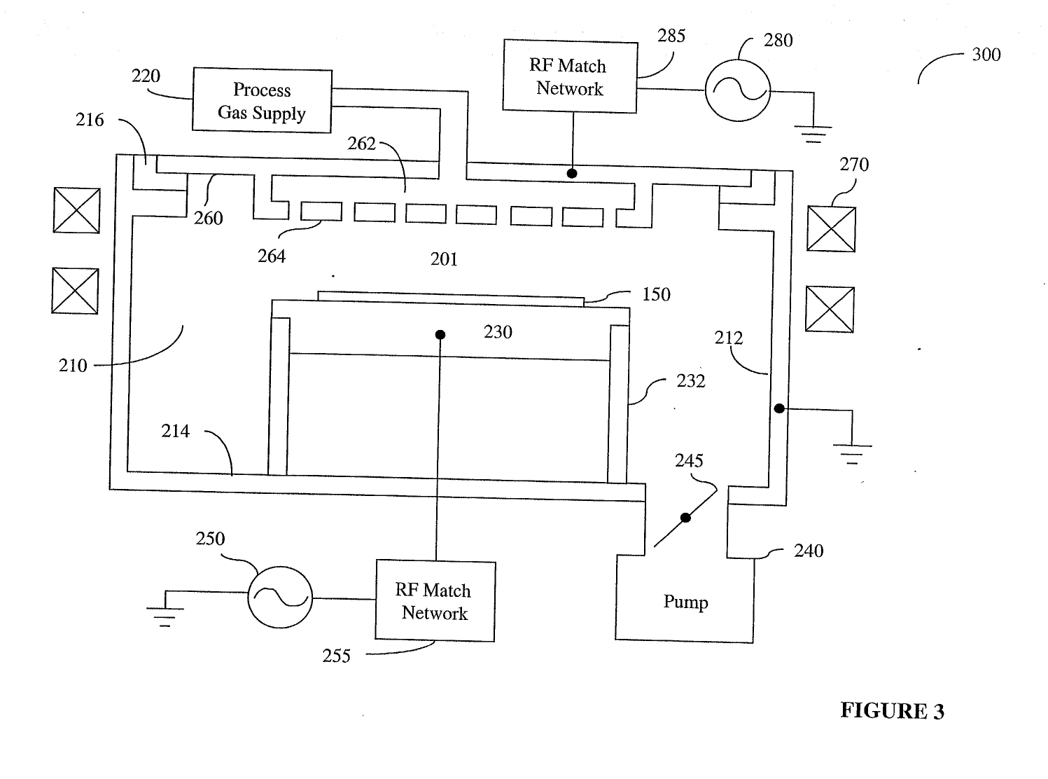

The etching process of the present invention can also be carried out in a dual powered plasma reactor, such as, for example, a triode-type reactor commercially available from Applied Materials Inc., Santa Clara, Calif. FIG. 3 illustrates an exemplary configuration of a dual powered plasma reactor 300 comprising a chamber 210 enclosed by a wall 212, a base 214, and a ceiling 260. The chamber includes a process zone 201 comprising a volume of about 5,000 to about 50,000 cm³. The reactor 300 further comprises a process gas supply 220 that supplies process gases into the chamber 210 through a gas manifold 262 and a gas distribution plate (GDP) 264 at the ceiling 260 of the chamber 210. Spent process gas and etch products are pumped out by one or more pumps from an opening at the base 214. A throttle valve 245 at the opening controls the pressure in the chamber 210. The wall 212 and the base 214 are usually made of aluminum with anodized aluminum coating on at least the surfaces facing the inside of the chamber 210, and are typically grounded. The ceiling 260 and the GDP are made of conductive material and are electrically isolated from the wall 212 by an insulator ring 216. The chamber 210 further includes a pedestal 230 that supports the substrate 150 in the chamber 210. The pedestal 230 is electrically isolated from the base 214 by an insulator support ring 232, and is connected to a first (bottom) radio frequency (RF) power source 250 through a first (bottom) impedance match network 255. A second (top) RF power source 280 is connected through a second (top) impedance match network 285 to the ceiling 260.

Reactor 300 may also include plural magnets 270 around the chamber wall 212 to provide a slowly rotating magnetic field in the chamber 210. The magnets may be electromagnets driven with respective phases of a low frequency (e.g., 0.1-0.5 Hertz) AC current source (not shown). Alternatively, the magnets may be permanent magnets mounted on a slowly rotating support structure (not shown) rotating at, for example, 0.1-0.5 revolutions per second.

The two power sources 250 and 280 produce RF power at different frequencies. The frequency of the first RF power source is typically in the range of 2-13.56 MHz, and the frequency of the second RF power source is typically in the range of 13.56-180 MHz. In one embodiment of the present invention, the frequency of the first and second RF power sources is 13.56 MHz and 60 MHz, respectively. Filtering is employed to minimize the interaction between RF signals from the two RF power supplies 250 and 280. In one embodiment of the present invention, such filtering is accomplished by using an inductor in the match network 285 that grounds the ceiling electrode 260 at 13.56 MHz while appearing to be a high impedance for a 60 MHz signal. Similarly, a capacitor can be used in the match network 255 to ground the pedestal electrode 230 at 60 MHz while appearing to be a high impedance for 13.56 MHz signal. Therefore, separate RF power at different frequencies can be independently coupled into the chamber 210.

The operation of the reactor 300 is similar to that of the reactor 200. The reactor 300, however, offers more advantages in striation reduction and chamber cleaning because of the second RF power source 280. The much higher dissociation rate offered by the high frequency power source 280 is found to help further reduce striation. Also, the second RF power source 280 can generate a plasma in the chamber 210 without causing the pedestal 230 to be significantly biased with respect to the plasma. Reactor 300 thus facilitates the application of a chamber cleaning process of the present invention, in which an oxygen or oxygen/nitrogen plasma is maintained mainly by the second RF power source 280, while the first RF power source is turned off or to a low level such that the DC voltage between the plasma and the pedestal 230 is not significant. As a result, the average energy of plasma generated ions impinging on the pedestal is not significant enough to cause damage to the surface of the electrostatic chuck on the pedestal 230.

FIGS. 2 and 3 illustrate only two exemplary configurations of the many plasma reactors that can be used to practice the present invention. For example, the reactor 300 may include other power sources in addition to or in place of the RF power source 250 or 280, and power can be coupled into the chamber 210 to strike and maintain a plasma therein through differently configured coupling hardware such as known in the art, without affecting the application of the present invention. For example, RF power can be inductively coupled into a plasma by applying a RF voltage to a coil placed near a quartz window at the ceiling or wall of a vacuum chamber. The frequency of the RF power applied to the inductor coil is typically from about 50 KHZ to about 60 MHz, and more typically about 13.56 MHz. The plasma generated by inductively coupled RF power also has the characteristics of higher dissociation rate and insignificant ion bombardment on the surrounding surfaces, and can also be used to improve striation and to run a plasma for chamber cleaning.

The etching of vias or contacts in dielectrics typically comprises a main etch step followed by an over etch step. FIG. 1(a) depicts the dielectric layer 120 at the beginning of the main etch step, FIG. 1(b) depicts the dielectric layer 120 in the middle of the main etch step, FIG. 1(c) depicts the dielectric layer 120 at the beginning of the over etch step, and FIG. 1(d) depicts the dielectric layer 120 at the end of the over etch step. The main etch step advances the feature bottom surface 106 until it almost reaches the top surface of the underlying layer 130. The over etch step clears away any residual dielectric layer left in the feature 101, such as, for example, at the bottom corners 109 of the feature 101. The main etch step may run for a time period predetermined from etch rate data obtained from test runs, or, it may run until an endpoint is detected by a conventional optical endpoint measurement device incorporated in the reactor 200. The present invention provides a novel main etch process that produces much less striation than conventional main etch processes. The main etch process can be followed by any over etch process suitable for the dielectric material 120 and the underlying material 130. For example, when the dielectric material 120 is silicon oxide and the underlying material 130 is polysilicon, the over etch process should be selected to etch the silicon oxide with high etching selectivity with respect to polysilicon.

A chamber cleaning process can be carried out after the over etch step. When a dual-powered reactor, such as reactor 300, is used, after the substrate has been transferred out of the chamber 210, an oxygen or oxygen/nitrogen mixture plasma can be ignited in the chamber 210 to clean off the polymeric deposits left by the etching process. The pressure in the chamber during the chamber clean process is not critical, and the cleaning plasma is typically ignited and maintained by the top power source 280 or any other power source that is capable of maintaining a plasma in the chamber 210 without causing a significant DC voltage between the plasma and the surrounding objects, such as the pedestal 230. The amount of power coupled into the chamber 210 from the top power source is typically between 500-3000 W.

The process gas used in the etching process comprises a fluorocarbon gas. The process gas further includes oxygen and a hydrogen-containing gas. The fluorocarbon gas contributes fluorine and CFₓ species in the plasma that etch the dielectric layer 120 by reacting with the silicon and oxygen content in the dielectric layer 120 to form volatile etch products. For normal dielectrics such as oxide, the etching reactions may include,

2CF₂+SiO₂→SiF₄+2CO,

where both SiF₄ and CO are volatile and can be pumped out of the chamber 210. At the same time, some CFₓ species (x=1, 2, or 3) may form polymeric deposits by recombining with each other or with other species on the feature surfaces before reacting with the dielectric layer. These passivating polymeric deposits accumulate more on the feature sidewalls 105 because the sidewalls 105 are subject to less ion bombardment from the plasma. Thus, the passivating deposits help in preventing the feature 101 from being etched sideways and in achieving anisotropic etching.

The fluorocarbon gas can be one or more gases selected from, for example, CF₄, C₂F₆, C₃F₈, C₃F₆, C₄F₆, C₄F₈, C₄F₁₀, CH₃F, CHF₃, C₂HF₅, CH₂F₂, C₂H₄F₂, and C₂H₂F₄.

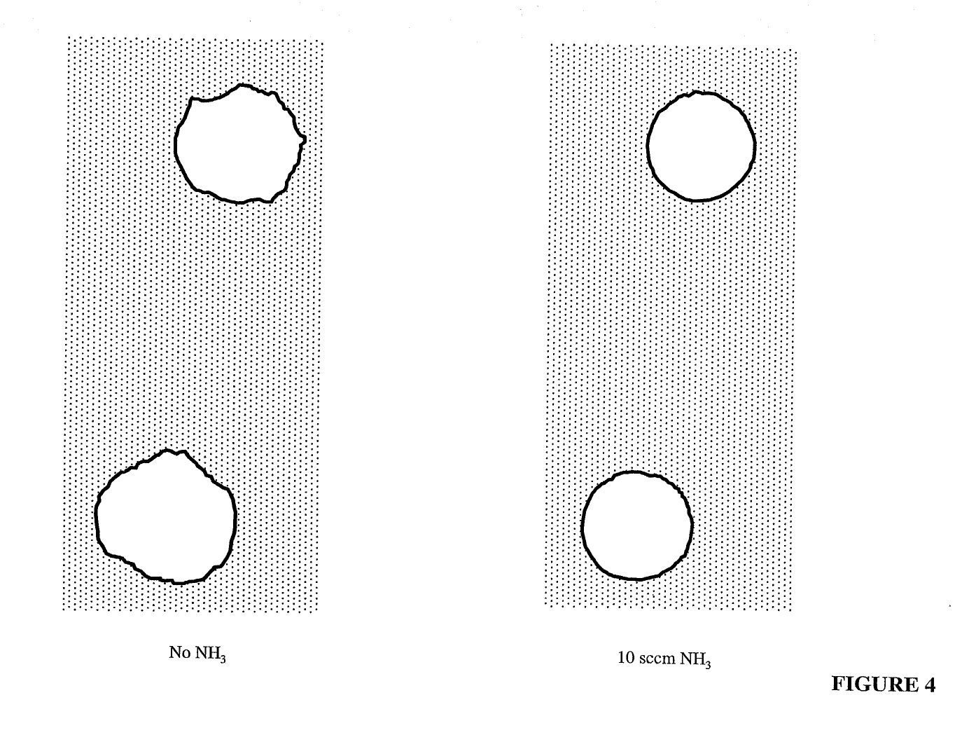

The oxygen gas helps to reduce the polymer deposition by reacting with the carbon content in the polymeric deposits to form volatile CO_{y} (y=1, 2) products that can be pumped out of the chamber 210. The hydrogen-containing gas includes H₂ or any of the NH₃-generating gases that are capable of generating NH₂⁻, NH₃, or NH₄⁺, ions and neutral radicals in the plasma₆, including, for example, NH₃, NH₄OH, CH₃NH₂, C₂H₅NH₂, C₃H₈NH₂, and mixtures thereof. Combined with the presence of oxygen, the hydrogen-containing gas provides the unexpected result of reduced striation. FIG. 4 shows peripheral drawings reproduced from two scanning electron micrographs (SEM) of etched holes in a top-down view. The holes on the left were etched without a hydrogen-containing gas, and the holes on the right were etched with 10 standard cubic centimeters per minute (sccm) volumetric flow of NH₃. As shown in FIG. 4, the periphery of the holes etched with NH₃ is much smoother, indicating much reduced striation.

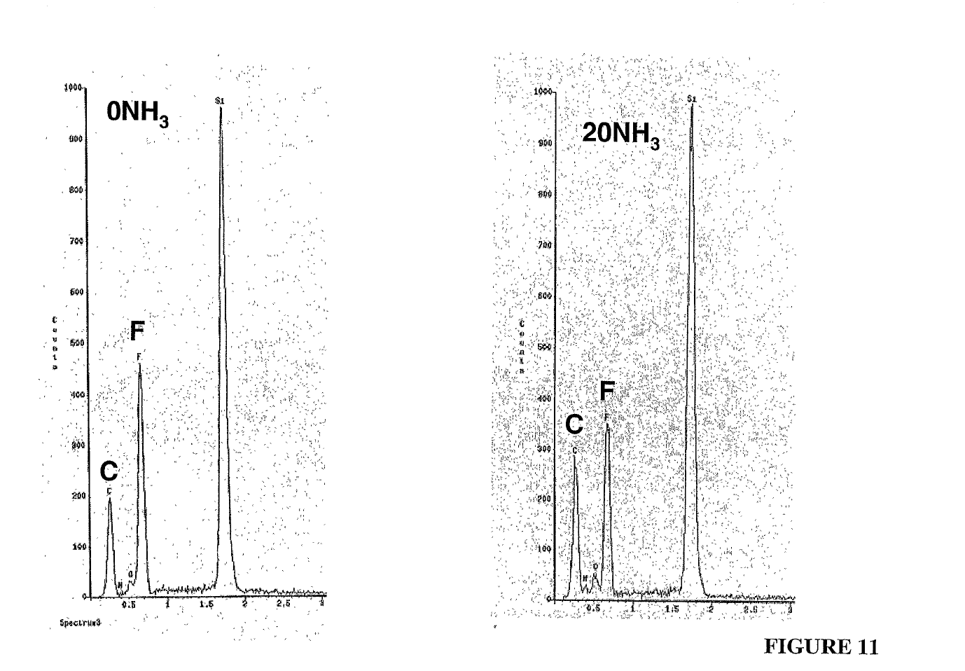

FIG. 11 displays the results of Energy-Dispersive X-Ray Spectroscopy (EDX) analysis of the atomic composition on the surfaces of features etched with Examples 1 and 5 in Table I. The EDX graph on the left corresponds to features etched without a hydrogen-containing gas, and the EDX graph on the right corresponds to features etched with 20 sccm volumetric flow of NH₃. As shown in FIG. 11, NH₃ addition in the process gas makes the polymeric deposition on the etched surface more carbon-rich. This is likely due to the hydrogen-containing content in the etching gas that takes away fluorine from the passivating polymeric deposits on the feature surfaces. The higher carbon concentration in the polymer may be associated with the reduced striation.

The volumetric flow rate of each gas in the process gas depends on many factors, including the configuration of the reactor used to carry out the etching process, the size of the substrate, and the specific gases used. In one embodiment of the present invention, when C₄F₆ is used as the fluorocarbon gas and NH₃ is used as the hydrogen-containing gas, the volumetric flow ratio of fluorocarbon:oxygen gas is about 1:1, and the volumetric flow ratio of oxygen:NH₃ gas is from about 5:2 to about 5:1. The volumetric flow ratios can also be tailored for different combinations of materials and feature geometry, such as feature aspect ratios, to achieve specific etching selectivities, etch rates, or feature geometry without deviating from the scope of the present invention.

In one embodiment of the present invention, an inert gas is added to the process gas to help control the profile of the etched features. Suitable inert gases include argon, helium, neon, xenon, and krypton, of which argon is most often used. In one embodiment of the present invention, the volumetric flow ratio of the inert:fluorocarbon gas is from about 10:1 to 20:1.

### EXAMPLES

The following examples illustrate use of the present invention for etching the dielectric layers 120 on a semiconductor substrate 150, such as a silicon wafer of 200 mm (8 inch) or 300 mm (12 inch) diameter.

During the etching process, the substrate 150 is placed on the pedestal 230 of the reactor 200 or 300, and the chamber 210 is maintained at a pressure of about 10-100 mTorr (mT), and more typically at about 30 mT. Process gas is introduced into the process chamber 210 through the GDP 264. For 200 mm wafers, the process gas comprises about 10-50 sccm C₄F₆, 10-50 sccm O₂, 5-20 sccm NH₃, and 100-750 sccm Argon. For 300 mm wafers, the process gas comprises about 20-100 sccm C₄F₆, 20-100 sccm O₂, 10-40 sccm NH₃, and 200-1500 sccm Argon. A plasma is generated in the process zone 201 that etches the dielectric layer 120 on the substrate 150. The plasma is generated by applying a RF voltage to the pedestal 230 having a power level of about 1000-2500 Watts for 200 mm wafers or about 2000-5000 Watts for 300 mm wafers. A rotating magnetic field (B-field) of about 0-50 Gauss can also be applied to the process zone 201. When the reactor 300 is used to perform the etching process, a second RF voltage having a power level of about 0-500 W for 200 mm wafers or 0-1000 W for 300 mm wafers can be applied to the ceiling electrode 260.

The wafer 150 is maintained at a temperature sufficiently high to volatilize etch products, and sufficiently low so that a layer of passivating deposits is retained on the sidewalls 105 of freshly etched feature 101. Typically, the substrate 150 is kept at about room temperature, e.g., about 20° C., using a flow of helium on the backside of the substrate 150. The pressure of the backside helium is maintained at about 15 Torr. The chamber wall 212 is kept at an elevated temperature, e.g., about 60° C., using a cooling or heating mechanism known conventionally for maintaining chamber wall temperature. The higher temperature of the wall 212 than that of the substrate 150 helps reduce polymeric deposits on the chamber wall 212.

Table I lists some of the process parameters such as RF power, pressure, process gas composition and flow rates, magnetic field strength (B-field), etc. used to etch dielectrics on 200 mm wafers in a series of examples of the present invention. Since the actual process parameters are dependent upon the size of the wafer, the volume of the chamber 210, and on other hardware configurations of the reactor used to carry out the etching process, the process parameters listed in Table I are exemplary and the present invention is not limited to these parameters.

Scanning electron micrograph (SEM) photos of etched test wafers were used to measure etch rate and etching selectivity with respect to photoresist (PR) mask, and to observe striation. Table II lists some of the results of measurements from a set of 200 mm test wafers etched with the process parameters listed in Table I. As listed in Table II, the main etch processes in the examples 2-12 in Table I result in etch rates higher than 4000 Å/min, and photoresist selectivity ratios higher than 4.5:1.

TABLE I

| | Process Gas flow rate | | | | Pres- | RF Power (W) | | |
|---|---|---|---|---|---|---|---|---|
| | (sccm) | | | | sure | | ceil- | B-field |
| | C₄F₆ | NH₃ | O₂ | Ar | (mT) | pedestal | ing | (G) |
| Example 1 | 33 | 0 | 33 | 500 | 30 | 1200 | 500 | 50 |
| Example 2 | 33 | 5 | 33 | 500 | 30 | 1200 | 500 | 50 |
| Example 3 | 33 | 10 | 33 | 500 | 30 | 1200 | 500 | 50 |
| Example 4 | 33 | 15 | 33 | 500 | 30 | 1200 | 500 | 50 |
| Example 5 | 33 | 20 | 33 | 500 | 30 | 1200 | 500 | 50 |
| Example 6 | 33 | 10 | 33 | 500 | 30 | 1500 | 500 | 50 |
| Example 7 | 40 | 10 | 40 | 500 | 30 | 1500 | 500 | 50 |
| Example 8 | 40 | 10 | 40 | 500 | 30 | 1500 | 500 | 0 |
| Example 9 | 40 | 10 | 40 | 500 | 30 | 1500 | 0 | 50 |
| Example 10 | 40 | 12 | 40 | 500 | 30 | 1500 | 500 | 50 |
| Example 11 | 40 | 12 | 40 | 700 | 30 | 1500 | 500 | 50 |
| Example 12 | 40 | 12 | 40 | 500 | 30 | 1500 | 300 | 50 |

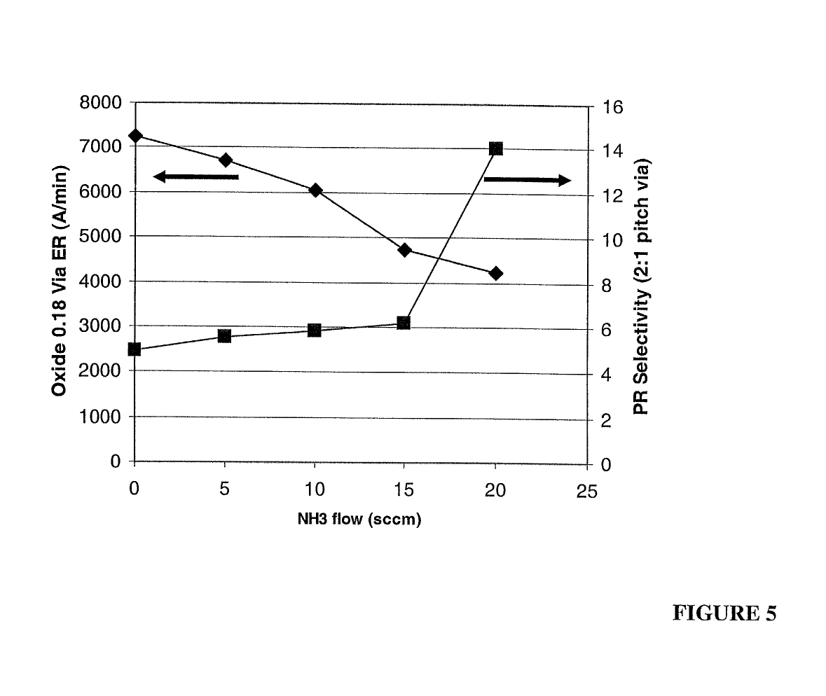

FIGS. 5-10 illustrate some of the process trends derived from the test wafer measurements. The process trends shown in FIGS. 5-10 includes the trend of change in etch rate and PR selectivity in response to changes in the NH₃ flow rate, C₄F₆ or O₂ flow rate, argon flow rate, bottom RF power, top RF power, and magnetic field in the chamber, respectively. As shown in FIG. 5, higher NH₃ flow rate results in decreased etch rate and increased PR selectivity. From the SEM pictures of the etched wafers, higher NH₃ flow rate also results in reduced striation.

TABLE II

| | Etch Rate (Å/min) | PR Selectivity |
|---|---|---|
| Example 1 | 7240 | 4.9:1 |
| Example 2 | 6710 | 5.8:1 |
| Example 3 | 6060 | 5.2:1 |
| Example 4 | 4730 | 6.2:1 |
| Example 5 | 4210 | 14:1 |
| Example 6 | 6530 | 4.7:1 |
| Example 7 | 6950 | 5.6:1 |
| Example 8 | 6850 | 6.1:1 |
| Example 9 | 5470 | 5.4:1 |
| Example 10 | 7160 | 6.4:1 |
| Example 11 | 6000 | 6.0:1 |
| Example 12 | 6320 | 6.0:1 |

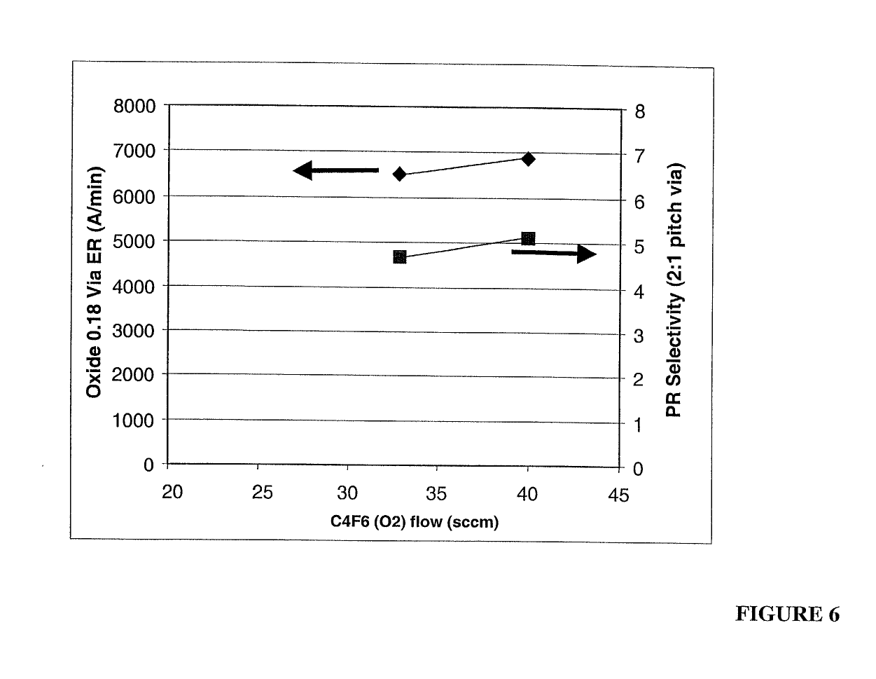

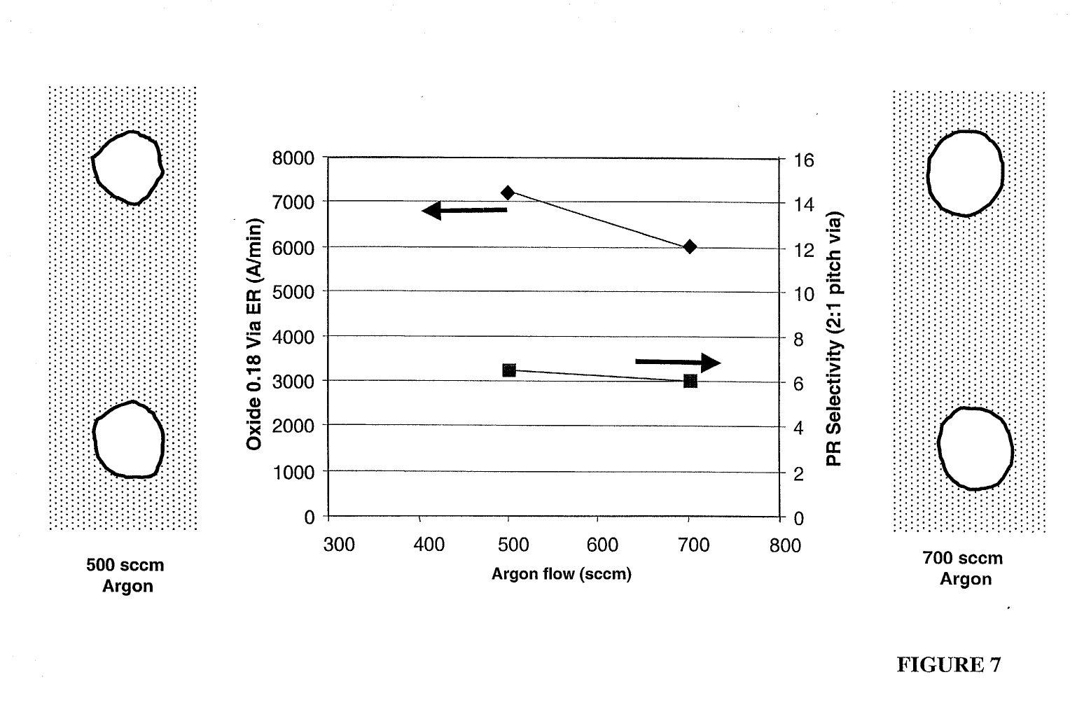

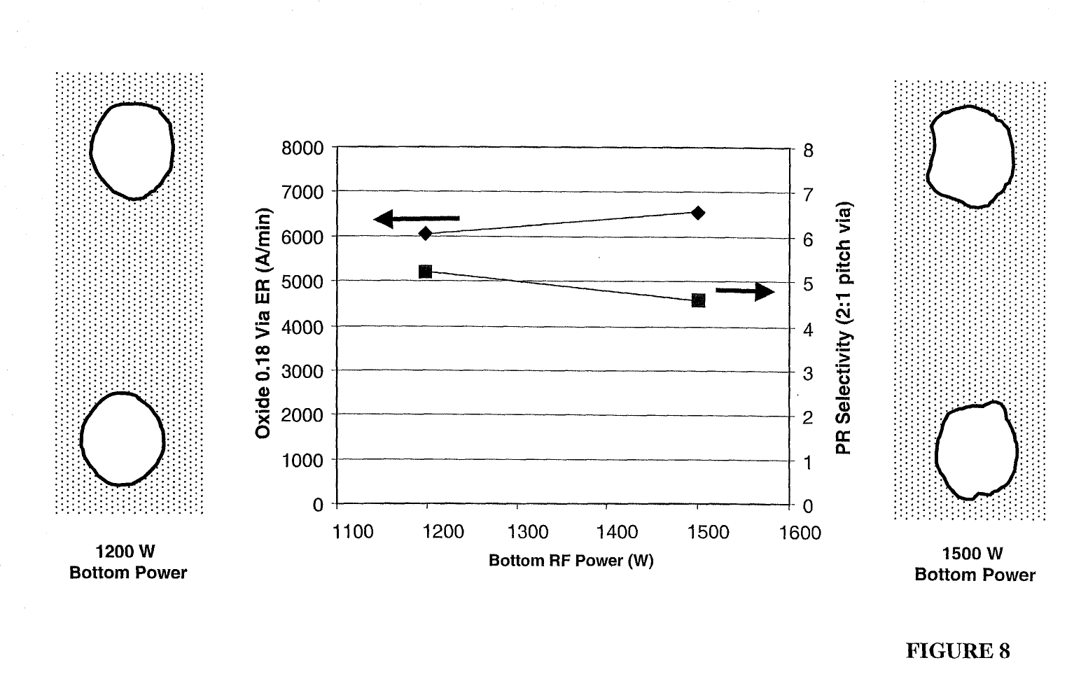

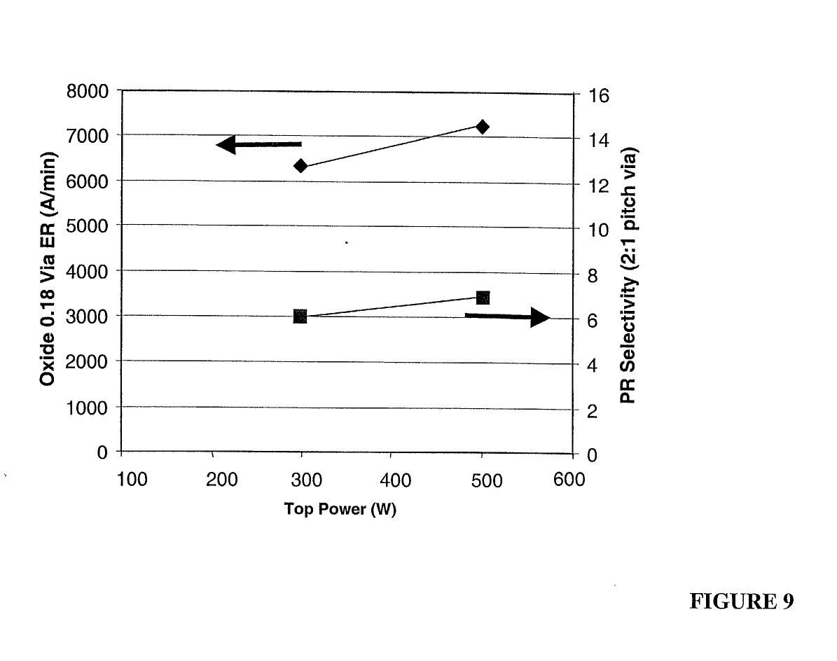

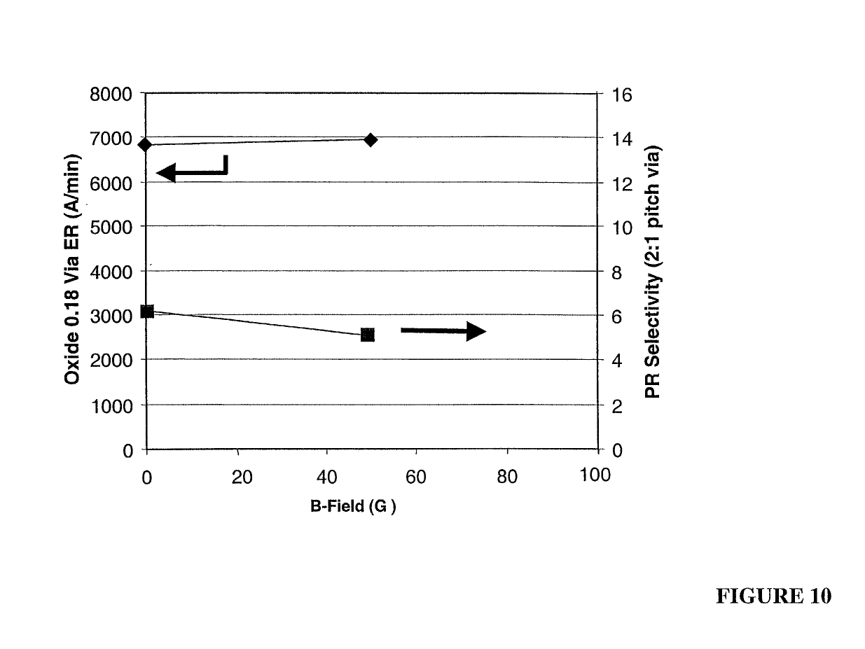

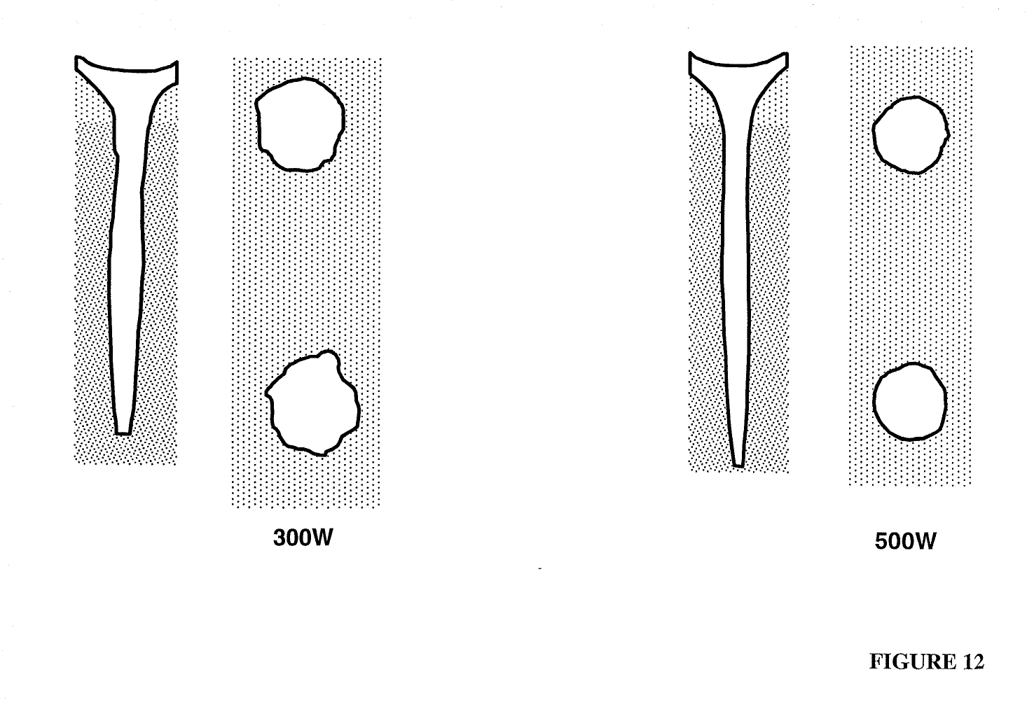

FIG. 6 shows that higher C₄F₆ and O₂ flow rate results in increased etch rate and increased selectivity. FIG. 7 shows that higher Argon flow rate results in decreased etch rate and decreased selectivity. But high Argon flow rate has been found to improve etched feature profile and to reduce striation, as shown in FIG. 7 by the peripheral drawings reproduced from SEM pictures in top-down view of holes etched using different Argon flow rates. FIG. 8 shows that higher bottom RF power results in increased etch rate and decreased selectivity. Higher bottom RF power has also been found to make striation worse, as shown in FIG. 8 by peripheral drawings reproduced from SEM pictures in top-down view of holes etched using different bottom power levels. FIG. 9 shows that higher top RF power results in increased etch rate and increased selectivity. Higher top RF power has also been found to reduce striation, as shown in FIG. 12 by the peripheral drawings reproduced from SEM pictures of holes etched using different top RF power levels. FIG. 10 shows that higher magnetic field in the chamber results in slightly increased etch rate but decreased selectivity. But the presence of a slowly rotating magnetic field of about 50 G has been found to help further reduce striation.

While the present invention has been described with reference to a few specific embodiments, the description is illustrative of the invention and is not to be construed as limiting the invention. Various modifications may occur to those skilled in the art without departing from the true spirit and scope of the invention as defined by the appended claims.

What is claimed is:

1. A method of etching a substrate having a dielectric layer with resist thereon, the method comprising:
providing a flow of a process gas into a process zone in which the substrate is situated, the process gas including a fluorocarbon gas, oxygen, and a hydrogen-containing gas; and
maintaining a plasma of the process gas in the process zone for a period of time; wherein the hydrogen-containing gas is selected from the group consisting of H₂, NH₃, NH₄OH, CH₃NH₂, C₂H₅NH₂, C₃H₈NH₂, and mixtures thereof.

2. The method of claim 1 wherein the volumetric flow ratio of the fluorocarbon:oxygen:hydrogen-containing gas is selected to provide a dielectric etch rate higher than 4000 Å/min, and a dielectric to photoresist etching selectivity ratio higher than 4.5:1

3. The method of claim 1 wherein the fluorocarbon gas is selected from the group consisting of CF₄, C₂ F₆, C₃F₈, C₃F₆, C₄F₆, C₄F₈, C₄F₁₀, CH₃F, CHF₃, C₂HF₅, CH₂F₂, and C₂H₄F₂ and mixtures thereof.

4. The method of claim 1 wherein the fluorocarbon gas is C₄F₆ and the hydrogen-containing gas is NH₃.

5. The method of claim 4 wherein the volumetric flow ratio of C₄F₆:O₂ is about 1:1.

6. The method of claim 1 wherein the fluorocarbon gas is C₃F₆ and the hydrogen-containing gas is NH₃.

7. The method of claim 1 wherein the volumetric flow ratio of oxygen:hydrogen-containing gas is in the range of 5:2 to 5:1.

8. The method of claim 1 wherein the process gas further comprises an inert gas selected from the group consisting of argon, xenon, neon, krypton, and helium.

9. The method of claim 8 wherein the inert gas is argon.

10. The method of claim 8 wherein the volumetric flow ratio of inert:fluorocarbon gas is in the range of 10:1 to 20:1.

11. The method of claim 1 wherein the gas pressure in the process zone is from about 10 mT to about 100 mT.

12. The method of claim 1 wherein the gas pressure in the process zone is about 30 mT.

13. The method of claim 1, further comprising providing a slowly rotating magnetic field in the process zone during the period of time.

14. The method of claim 1 wherein the plasma is maintained by at least two power supplies, including a first power supply and a second power supply, and wherein the average energy of plasma generated ions impinging on the dielectrics depends mainly on power coupled into the process zone from the first power supply.

15. The method of claim 14 wherein power from the second power supply is capacitively coupled into the plasma.

16. The method of claim 14 wherein power from the second power supply is inductively coupled into the plasma.

17. The method of claim 14 wherein power coupled into the process zone from the first power supply is in the range of about 1000 W to 5000 W.

18. The method of claim 14 wherein power coupled into the process zone from the second power supply is in the range of about 0 to 1000 W.

19. The method of claim 1 further comprising
removing the substrate from the process zone;
providing a flow of a cleaning gas into the process zone; and
maintaining a plasma of the cleaning gas.

20. The method of claim 19 wherein the cleaning gas is selected from the group consisting of oxygen and oxygen/nitrogen mixture.

21. The method of claim 19 wherein the cleaning plasma is at a DC electric potential that is not significantly different from the DC electric potentials of objects surrounding the process zone and in contact with the cleaning plasma.
